(19) United States
(12) Patent Application Publication
(10) Pub. No.: US 2026/0347576 A1
(43) Pub. Date: Nov. 5, 2026

(54) A FLAME RETARDANT INSULATING FILM

(71) Applicant: Illinois Tool Works Inc., Glenview, IL (US)

(72) Inventor: Run SU, Shanghai (CN)

(21) Appl. No.: 19/121,343

(22) PCT Filed: Oct. 30, 2023
(86) PCT No.: PCT/US2023/078205

§ 371 Date: Apr. 15, 2025

(30) Foreign Application Priority Data
Oct. 31, 2022 (CN) 202211348201.1

(51) Int. Cl. C08K 13/04; C08J 5/18; C08K 3/32; C08K 5/3492; C08K 5/52; C08K 7/00; H05K 5/02

(52) U.S. Cl. CPC C08K 13/04; C08J 5/18; H05K 5/0209; C08J 2323/12; C08J 2323/14; C08K 2003/323; C08K 5/34924; C08K 5/5205; C08K 7/00; C08K 2201/003; C08K 2201/014

(57) ABSTRACT

The present application provides a flame-retardant insulating film comprising a polypropylene, a halogen-free intumescent flame retardant, and a synergistic additive. The halogen-free intumescent flame retardant accounts for 39%-50% of the weight of the flame-retardant insulating film. The synergistic additive is a sheet-like inorganic material with a sheet diameter of 2-200 μm, and the synergistic additive accounts for 0.5%-6% of the weight of the flame-retardant insulating film.

### RELATED APPLICATIONS

This international application claims priority to Chinese Patent Application No. 202211348201.1, filed Oct. 31, 2022. The entirety of Chinese Patent Application No. 202211348201.1 is incorporated herein by reference.

### TECHNICAL FIELD

The present application relates to the field of films, in particular, to a flame-retardant insulating film and an electrical part comprising the flame-retardant insulating film.

### BACKGROUND

Flame-retardant insulating films are used to isolate various types of electronic devices or parts to avoid failure of electronic components between electronic devices and parts or in electronic devices or parts due to short circuit, breakdown and the like, and reduce the risk of ignition of electronic devices or parts, thereby ensuring the normal operation of various electronic components. Traditionally, insulating films are manufactured using halogenated flame-retardants. However, halogenated flame-retardants are harmful to the environment. To eliminate environmental impact, attempts have been made to manufacture flame-retardant insulating films using halogen-free flame-retardants.

### SUMMARY

The present application provides a flame-retardant insulating film, and the high-temperature resistant insulating film is used in electronic devices or parts to meet insulation and flame-retardant requirements for electronic devices or parts.

In a first aspect, the present application provides a flame-retardant insulating film comprising a polypropylene, a halogen-free intumescent flame retardant, and a synergistic additive. The halogen-free intumescent flame retardant accounts for 39%-50% of the weight of the flame-retardant insulating film. The synergistic additive is a sheet-like inorganic material with a sheet diameter of 2-200 μm, and the synergistic additive accounts for 0.5%-6% of the weight of the flame-retardant insulating film.

In the flame-retardant insulating film described above, the sheet diameter of the sheet-like inorganic material is 4-80 μm.

In the flame-retardant insulating film described above, the sheet-like inorganic material comprises at least one of mica and talc powder.

In the flame-retardant insulating film described above, the polypropylene is a linear homopolymer or a copolymer polypropylene, and the polypropylene accounts for 45%-57% of the weight of the flame-retardant insulating film.

In the flame-retardant insulating film described above, the halogen-free intumescent flame retardant is selected from at least one of ammonium polyphosphate or a derivative thereof, melamine polyphosphate or a derivative thereof, and piperazine pyrophosphate or a derivative thereof.

In the flame-retardant insulating film described above, the halogen-free intumescent flame retardant is composed of ammonium polyphosphate or a derivative thereof and melamine polyphosphate or a derivative thereof, in which the ammonium polyphosphate or the derivative thereof accounts for 17%-35% of the weight of the flame-retardant insulating film and the melamine polyphosphate or the derivative thereof accounts for 10%-25% of the weight of the flame-retardant insulating film.

In the flame-retardant insulating film described above, the halogen-free intumescent flame retardant is composed of piperazine pyrophosphate or a derivative thereof, and melamine polyphosphate or a derivative thereof, in which the piperazine pyrophosphate or the derivative thereof accounts for 17%-35% of the weight of the flame-retardant insulating film and the melamine polyphosphate or the derivative thereof accounts for 10%-25% of the weight of the flame-retardant insulating film.

The flame-retardant insulating film described above further comprises a flame-retardant additive and a charring agent. The flame-retardant additive accounts for less than 15% of the weight of the flame-retardant insulating film, the flame-retardant additive comprising melamine cyanurate. The charring agent accounts for less than 2% of the weight of the flame-retardant insulating film, the charring agent being selected from at least one of pentaerythritol and triazine.

The flame-retardant insulating film described above further comprises an additional flame retardant, which accounts for less than 5% of the weight of the flame-retardant insulating film, the additional flame-retardant comprising an alkyl hypophosphite.

The flame-retardant insulating film described above has a thickness of 0.08-3 mm.

The flame-retardant insulating film described above is manufactured by a melt extrusion molding process.

In a second aspect, the present application provides an electrical device, which comprises a housing and an electrical part positioned within the housing. The electrical part is enclosed or partially enclosed by the flame-retardant insulating film according to the present application.

The electrical device described above is a power adapter or a power supply unit.

In a third aspect, the present application provides a formulation of a flame-retardant insulating material, the formulation comprising a polypropylene, a halogen-free intumescent flame retardant, and a synergistic additive. The halogen-free intumescent flame retardant accounts for 39%-50% of the weight of the flame-retardant insulating film. The synergistic additive is a sheet-like inorganic material with a sheet diameter of 2-200 μm, and the synergistic additive accounts for 0.5%-6% of the weight of the flame-retardant insulating film.

### BRIEF DESCRIPTION OF THE DRAWINGS

FIGS. 1A and 1B are structural schematic diagrams of an electrical device of one example comprising a flame-retardant insulating film of the present application.

### DETAILED DESCRIPTION

Various specific embodiments of the present application will be described below with reference to the accompanying drawings that form a part of the present specification. It should be understood that while terms denoting orientation, such as “front,” “rear,” “upper,” “lower,” “left,” “right,” “top,” “bottom,” “inside,” “outside,” etc., are used in the present application to describe various exemplary structural parts and elements of the present application, these terms are used herein for convenience of illustration only and are determined based on the exemplary orientations shown in the accompanying drawings. Since the examples disclosed in the present application may be disposed in different orientations, these terms denoting orientation are for illustrative purposes only and should not be considered as limiting.

In the present application, unless otherwise specified, all equipment and materials may be purchased from the market or are commonly used in the industry. The methods in the following examples, unless specifically stated, are conventional methods in this field.

Polypropylene film materials are a commonly used plastic material with excellent mechanical performance, processing and molding performance, and relatively low cost. They are widely used, for example, in the electrical field as insulating films. However, the flame-retardant performance of polypropylene film materials per se is poor, and it is often necessary to improve the flame-retardant performance of the polypropylene film materials by compounding the flame retardant in order to obtain a flame-retardant insulating film. The inventors of the present application have found that the flame-retardant performance of flame-retardant insulating films is related to the thickness and amount of flame retardant added to the flame-retardant insulating film. In general, the greater the thickness of the flame-retardant insulating film, the better the flame-retardant effect. However, thick flame-retardant insulating films are unable to adapt to the lightweight and miniaturization development requirements of electrical parts, such as power adapters and batteries. In order to meet the lightweight and miniaturization development requirements of electrical parts, such as power adapters and batteries, it is desirable to manufacture thinner flame-retardant insulating films.

The inventors of the present application have found that the flame-retardant performance of flame-retardant insulating films may also be improved by increasing the amount of flame retardant added to the flame-retardant insulating film. However, the inventors of the present application have found that increasing the amount of flame-retardant may lead to a decrease in the mechanical performance and processing performance of the flame-retardant insulating film, resulting in uneven surfaces and the like. Also, a halogen-free flame retardant is used as the flame retardant to eliminate the environmental impact of the flame retardant. In contrast, halogen-free flame retardants are costly, so increasing the amount of halogen-free flame retardant used may lead to higher production costs.

The halogen-free flame-retardant used in the flame-retardant insulating film of the present application is a halogen-free intumescent flame retardant. The inventors of the present application have found that the use of a small amount of sheet-like inorganic material as the synergistic additive in flame-retardant insulating films may have synergistic effects with halogen-free intumescent flame retardants and is capable of ensuring that the flame-retardant insulating film has good flame-retardant performance without requiring a thick flame-retardant insulating film or increasing the amount of halogen-free intumescent flame retardant. Therefore, the present application is capable of providing a flame-retardant insulating film that is environmentally friendly, thin, and has good flame-retardant performance while using a small amount of flame retardant.

The flame-retardant insulating film of the present application comprises a polypropylene, which weight accounts for 45%-57% of the weight of the flame-retardant insulating film. In some examples, the weight of the polypropylene accounts for 47-55% of the weight of the flame-retardant insulating film. In some examples, the polypropylene is a linear homopolymer or a linear copolymer polypropylene.

The flame-retardant insulating film of the present application further comprises a halogen-free intumescent flame retardant, which weight accounts for 39%-50% of the weight of the flame-retardant insulating film. In some examples, the weight of the halogen-free intumescent flame retardant accounts for 40-47% of the weight of the flame-retardant insulating film. The halogen-free intumescent flame retardant is selected from at least one of ammonium polyphosphate (APP), or a derivative thereof, melamine polyphosphate (MPP), or a derivative thereof, and piperazine pyrophosphate (PAPP), or a derivative thereof. In some examples, the halogen-free intumescent flame retardant is composed of APP or a derivative thereof and MPP or a derivative thereof, the weight of the APP or the derivative thereof accounts for 17%-35% or 18-30% of the weight of the flame-retardant insulating film, and the weight of the MPP or the derivative thereof accounts for 10%-25% or 10-20% of the weight of the flame-retardant insulating film. In some other examples, the halogen-free intumescent flame retardant is composed of PAPP or a derivative thereof and MPP or a derivative thereof, the weight of the PAPP or the derivative thereof accounts for 17%-35% or 18-30% of the weight of the flame-retardant insulating film, and the weight of the MPP or the derivative thereof accounts for 10%-25% or 10-20% of the weight of the flame-retardant insulating film.

The flame-retardant insulating film of the present application further comprises a synergistic additive, which is a sheet-like inorganic material, and which weight accounts for 0.5%-6% of the weight of the flame-retardant insulating film. In some examples, the weight of the synergistic additive accounts for 1%-4% of the weight of the flame-retardant insulating film. The sheet-like inorganic materials used in the present application comprises at least one of mica and talc powder. In some examples, the sheet diameter of the sheet-like inorganic material used in the present application is 2-200 μm. The inventors of the present application have discovered that when the sheet diameter of the sheet-like inorganic material is less than 2 μm, the flame-retardant performance of the flame-retardant insulating film decreases, and when the sheet diameter is greater than 200 μm, the processing performance and mechanical performance of the flame-retardant insulating film decreases. In some examples, the sheet diameter of the sheet-like inorganic material used in the present application is 4-80 μm. The use of a synergistic flame retardant in the flame-retardant insulating film of the present application ensures that the flame-retardant insulating film has excellent flame-retardant performance without requiring a large amount of halogen-free intumescent flame retardant or having the flame-retardant insulating film manufactured to be very thin. The flame-retardant insulating film of the present application may be manufactured to have a thickness of only 0.08-3 mm, 0.1-2.5 mm, or 0.1-2 mm, while still having a flame-retardant performance of grade V-O under the UL-94 test standard. At the same time, the flame-retardant insulating film of the present application has excellent processing and mechanical performance without requiring a large amount of halogen-free intumescent flame retardant. In some examples, the insulating film of the present application is manufactured with a structure having a single layer or a plurality of layers.

The synergistic additive and halogen-free intumescent flame retardant used in the present application are capable of synergizing, improving the flame-retardant performance of the halogen-free intumescent flame retardant, thereby reducing the amount of halogen-free intumescent flame retardant used. In particular, the sheet-like inorganic material of the present application has a layered structure that is capable of being split to provide a thin, flexible sheet. The sheet-like inorganic material used in the present application is chemically inert and has excellent thermal stability, which extends flame-retardant effects and promotes charring in the present application. The crystalline structure of the sheet-like inorganic material affects the synergy with the halogen-free intumescent flame retardant. Tetrahedral SiO4 sheets on both sides of the space between layers results in better synergistic effects. Silicate strengthens the carbon- and charcoal-containing layer produced by the halogen-free intumescent flame retardant during combustion, further strengthens the physical barrier, protects the plastic matrix from the heat of combustion and isolates oxygen, slowing the freeing of flammable substances during combustion and decomposition of polymers. Also, the sheet-like inorganic material is conducive to the capture of free radicals, disrupts the combustion cycle, and has a synergistic effect with plastic materials, increasing flame-retardant performance while reducing the content of flame retardants in the formulation.

The flame-retardant insulating film of the present application may further comprise a flame-retardant additive, which weight accounts for 0%-15% of the weight of the flame-retardant insulating film. In some examples, the weight of the flame-retardant additive accounts for 0-10% of the weight of the flame-retardant insulating film. In some examples, the flame-retardant additive comprises melamine cyanurate (MCA).

The flame-retardant insulating film of the present application may further comprise a charring agent, which weight accounts for 0%-2% of the weight of the flame-retardant insulating film. In some examples, the charring agent is selected from at least one of pentaerythritol and triazine.

The flame-retardant insulating film of the present application may further comprise an additional flame retardant, which weight accounts for 0%-5% of the weight of the flame-retardant insulating film. In some examples, the weight of the additional flame retardant accounts for 0%-2% of the weight of the flame-retardant insulating film. In some examples, the additional flame retardant comprises an alkyl hypophosphite. In some examples, the alkyl hypophosphite is diethyl hypophosphite.

The flame-retardant insulating film of the present application may also comprise a functional additive. In some examples, the weight of the functional additive accounts for 0%-10% of the weight of the flame-retardant insulating film. In some examples, the functional additive is selected from at least one of a lubricant and a colorant.

Although the composition of the flame-retardant insulating film and the content of the various components is described in the specification of the present application above, it should be understood that the above formulation of the composition of the flame-retardant insulating film and the content of the various components may be used to formulate other flame-retardant insulating products.

The effect of the flame-retardant insulating film of the present application is illustrated below by means of some specific examples of the present application and comparative examples of the film. Table 1 shows the components and content of the various components in these specific examples and comparative examples of the flame-retardant insulating film, as well as their respective flame-retardant performance and tensile strength data.

The examples and comparative examples of the flame-retardant insulating film in Table 1 were prepared according to the following method: The feedstock of each component in Table 1 was weighed according to the weight percent content of the components in Table 1, added to a high-speed mixer and mixed for 10 minutes, and the rotational speed of the high-speed mixer was 500 rpm. The mixed feedstock was added to a twin screw extruder for extrusion, cooling and granulation. The temperature of the twin screw extruder was 230 °C, and the screw rotational speed was 300 rpm. The obtained granules were dried, extruded into films, and cut to 0.5 mm-thick standard test pieces for performance testing. The flame-retardant performance was tested based on UL-94 test standards. The tensile strength was tested based on ASTM D-882 test standards.

TABLE 1

| | | | | | | Comparative | Comparative |
|---|---|---|---|---|---|---|---|
| | Example 1 | Example 2 | Example 3 | Example 4 | Example 5 | Example 1 | Example 2 |
| Normal | 54 | 51.8 | 45 | 57 | 51 | 55 | 57 |
| polypropylene | | | | | | | |
| APP | / | / | 35 | / | / | 28 | / |
| MPP | 15 | 14 | 10 | 15 | 10 | 15 | 15 |
| PAPP | 28 | 25 | | 17 | 17 | / | 28 |
| MCA | / | / | 6 | 14 | 14 | / | / |
| Pentaerythritol | / | 0.5 | | / | 2 | 1 | / |
| Diethyl | / | 2 | | / | 5 | / | / |
| hypophosphite | | | | | | | |
| Montmorillonite | / | / | | / | / | 1 | / |
| Talc powder | / | 6 | | / | / | / | / |
| (sheet diameter | | | | | | | |
| of 10 μm) | | | | | | | |
| Mica (sheet | 3 | / | 3.8 | 1 | 1 | / | / |
| diameter of 50 | | | | | | | |
| μm) | | | | | | | |
| Lubricant | 0.2 | 0.2 | 0.2 | / | / | 0.2 | 0.2 |
| Performance | | | | | | | |
| UL-94 @0.5 mm | V-0 | V-0 | V-0 | V-0 | V-0 | V-2 | V-2 |
| Tensile strength | 29.6 | 33.5 | 26.2 | 31.6 | 28.9 | 29.5 | 30.7 |
| (MPa) | | | | | | | |

As shown in Table 1, comparing comparative examples 1 and 2, which are flame-retardant insulating films that do not use a sheet-like inorganic material, and examples 1-5, which use a sheet-like inorganic material with a sheet diameter of 2-200 μm, the flame-retardant insulating films of the present application have better flame-retardant performance than the films that do not use a sheet-like inorganic material. In particular, according to Table 1, comparative examples 1 and 2 are only capable of reaching the V-2 flame-retardant grade under the UL-94 test standard when halogen-free intumescent flame retardant accounting for 43% of the weight content is used and the thickness of the film is 0.5 mm. However, the flame-retardant insulating film of example 1 reaches the V-O flame retardant grade under the UL-94 test standard when using the same weight content of halogen-free intumescent flame retardant and with a thickness of 0.5 mm. Moreover, the flame-retardant insulating film of examples 2-5 are also capable of reaching the V-O flame-retardant grade when using a similar amount or less halogen-free intumescent flame retardant.

In addition, as shown in Table 1, because the content of halogen-free intumescent flame retardant in the flame-retardant insulating film of the present application does not need to be increased to improve the flame-retardant performance thereof, the flame-retardant insulating film in examples 1-5 is also capable of having excellent tensile strength and meeting the requirements for use similar to comparative examples 1 and 2 while ensuring the flame-retardant grade of examples 1-5.

Moreover, when preparing the flame-retardant insulating film of the present application according to the above examples, the inventors observed that the processing performance of the flame-retardant insulating film of the present application is good and capable of being continuously and stably produced.

The flame-retardant insulating film of the present application may be used in various electrical devices to enclose or partially enclose electrical parts in the electrical device so as to electrically isolate the electrical parts. Such an electrical device may be a power adapter, a power supply unit, a server power supply and a CPU perimeter, a lithium battery perimeter, or the like.

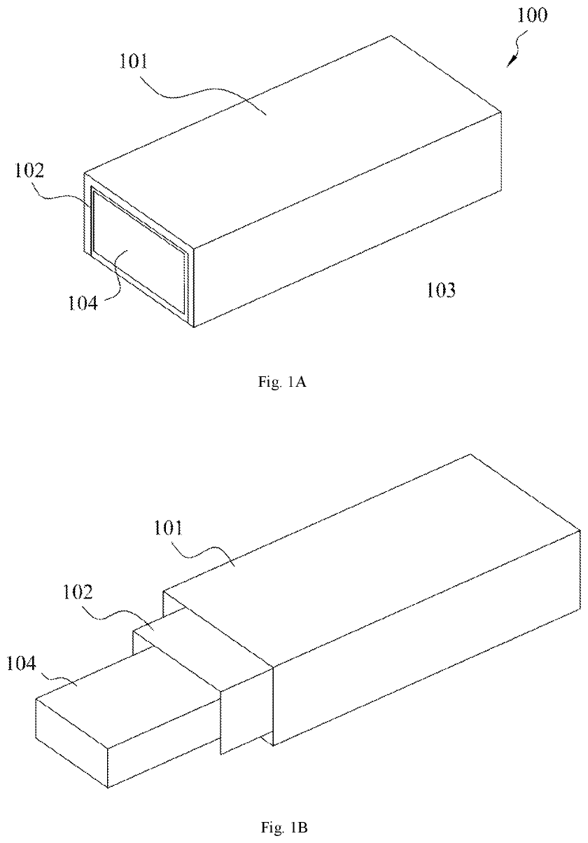

FIGS. 1A and 1B are structural schematic diagrams of an electrical device of one example comprising a flame-retardant insulating film of the present application. As shown in FIGS. 1A and 1B, the electrical device 100 comprises a housing 101 and an electrical part 104 disposed in the housing 101, a portion of the electrical part 104 being enclosed by the flame-retardant insulating film 102 of the present application to constitute electrical isolation of the electrical part 104.

The flame-retardant insulating film of the present application has at least the following technical effects:
1. Reduces the use of halogen-free intumescent flame retardants.
2. Even when the flame-retardant insulating film is very thin, it has excellent flame-retardant performance, thus meeting the miniaturization and lightweight requirements of electrical parts and it may be applied to more electrical parts.
3. Has excellent processing performance, and is capable of being continuously and stably produced.
4. Has excellent mechanical performance.

Although the present disclosure has been described in connection with the exemplary examples outlined above, various alternatives, modifications, variations, improvements, and/or substantial equivalents, whether known or foreseeable now or in the near future, may be apparent to those having at least ordinary skill in the art. Therefore, the exemplary examples of the present disclosure set forth above are intended to be illustrative and not limiting. Various changes may be made without departing from the spirit or scope of the present disclosure. Therefore, the present disclosure is intended to include all known or earlier developed alternatives, modifications, variations, improvements and/or substantial equivalents. The technical effects and technical problems in this specification are exemplary and not limiting. It should be noted that the examples described in this specification may have other technical effects and may solve other technical problems.

1. A flame-retardant insulating film, wherein the flame-retardant insulating film comprises:
a polypropylene;
a halogen-free intumescent flame retardant, which weight accounts for 39%-50% of the weight of the flame-retardant insulating film; and
a synergistic additive, which is a sheet-like inorganic material with a sheet diameter of 2-200 μm, and the weight of the synergistic additive accounts for 0.5%-6% of the weight of the flame-retardant insulating film.

2. The flame-retardant insulating film according to claim 2, wherein the sheet diameter of the sheet-like inorganic material is 4-80 μm.

3. The flame-retardant insulating film according to claim 2, wherein the sheet-like inorganic material comprises at least one of mica and talc powder.

4. The flame-retardant insulating film according to claim 1, wherein the polypropylene is a linear homopolymer or a linear copolymer polypropylene, and the weight of the polypropylene accounts for 45%-57% of the weight of the flame-retardant insulating film.

5. The flame-retardant insulating film according to claim 1, wherein the halogen-free intumescent flame retardant is selected from at least one of ammonium polyphosphate or a derivative thereof, melamine polyphosphate or a derivative thereof, and piperazine pyrophosphate or a derivative thereof.

6. The flame-retardant insulating film according to claim 5, wherein the halogen-free intumescent flame retardant is composed of ammonium polyphosphate or a derivative thereof and melamine polyphosphate or a derivative thereof, in which the ammonium polyphosphate or the derivative thereof accounts for 17%-35% of the weight of the flame-retardant insulating film and the melamine polyphosphate or the derivative thereof accounts for 10%-25% of the weight of the flame-retardant insulating film.

7. The flame-retardant insulating film according to claim 5, wherein:
the halogen-free intumescent flame retardant is composed of piperazine pyrophosphate or a derivative thereof, and melamine polyphosphate or a derivative thereof, in which the piperazine pyrophosphate or the derivative thereof accounts for 17%-35% of the weight of the flame-retardant insulating film and the melamine polyphosphate or the derivative thereof accounts for 10%-25% of the weight of the flame-retardant insulating film.

8. The flame-retardant insulating film according to claim 1, wherein:
the flame-retardant insulating film further comprises a flame-retardant additive and a charring agent;
in which the weight of the flame-retardant additive accounts for less than 15% of the weight of the flame-retardant insulating film, the flame-retardant additive comprising melamine cyanurate;
wherein the weight of the charring agent accounts for less than 2% of the weight of the flame-retardant insulating film, the charring agent being selected from at least one of pentaerythritol and triazine.

9. The flame-retardant insulating film according to claim 1, wherein the flame-retardant insulating film further comprises an additional flame retardant, which weight accounts for less than 5% of the weight of the flame-retardant insulating film, the additional flame-retardant agent comprising an alkyl hypophosphite.

10. The flame-retardant insulating film according to claim 1, wherein the flame-retardant insulating film has a thickness of 0.08-3 mm.

11. The flame-retardant insulating film according to claim 1, wherein the flame-retardant insulating film is manufactured by a melt extrusion molding process.

12. An electrical device, wherein the electrical device comprises a housing and an electrical part positioned within the housing, wherein:
the electrical part is enclosed or partially enclosed by the flame-retardant insulating film according to claim 1.

13. The electrical device according to claim 12, wherein the electrical device is a power adapter or a power supply unit.

14. A formulation of a flame-retardant insulating material, wherein the formulation comprises:
a polypropylene;
a halogen-free intumescent flame retardant, which weight accounts for 39%-50% of the weight of the flame-retardant insulating film; and
a synergistic additive, which is a sheet-like inorganic material with a sheet diameter of 2-200 μm, and the weight of the synergistic additive accounts for 0.5%-6% of the weight of the flame-retardant insulating film.
